(19) United States
(12) Patent Application Publication
(10) Pub. No.: US 2015/0004400 A1
(43) Pub. Date: Jan. 1, 2015

(54) SUPPORT ASSEMBLY FOR USE IN SEMICONDUCTOR MANUFACTURING TOOLS WITH A FUSIBLE BOND

(71) Applicant: Watlow Electric Manufacturing Company, St. Louis, MO (US)

(72) Inventors: John Lilleland, Morgan Hill, CA (US); Richard Phaler, Foster City, CA (US)

(21) Appl. No.: 13/930,475

(22) Filed: Jun. 28, 2013

(51) Int. Cl. H01L 21/683; B32B 43/00; H01J 37/34

(52) U.S. Cl. CPC H01L 21/6833; H01J 37/3414; B32B 43/006; H01L 2221/683; H01J 2237/332
USPC 428/332; 428/447; 279/128; 204/298.12; 156/711

(57) ABSTRACT

A support assembly includes a first functional element, a second functional element adjacent to the cooling plate, and an adhesive layer disposed between the cooling plate and the substrate. An intermediate layer is disposed between the cooling plate and the substrate. The intermediate layer has a melting temperature less than a temperature that the adhesive layer melts or decomposes at in order to provide for recycling of the support assemblycar.

### FIELD

The present disclosure relates to support assemblies for use in semiconductor manufacturing tools, and more particularly, support assemblies for use in electrostatic chucks.

### BACKGROUND

The statements in this section merely provide background information related to the present disclosure and may not constitute prior art.

An electrostatic chuck (ESC) can be used in semiconductor manufacturing tools such as plasma etchers. In particular, the ESC can hold a semiconductor wafer in the vacuum process chamber during processing. The wafer, ESC and process chamber can become a thermodynamic system where excess energy of the process is removed through components such as the ESC assembly. In particular, the ESC can control and maintain temperature of the wafer during the processing. For example, a coolant liquid can be circulated in a closed loop through internal channels in a chuck base to cool the wafer.

The ESC assembly can include various components or layers such as an ESC (support substrate), substrate, heater, and cooling plate. The layers can be formed into a stack, and neighboring layers can be bonded together with a thermally conductive elastomer adhesive. The adhesive provides a flexible mechanical attachment and also the thermal interfacing. Since the uniformity of the adhesive can affect thermal control of the ESC, certain adhesives such as silicone based adhesives can provide desired characteristics.

However, when the stack is desired to be reworked or refurbished, separation of the layers can be difficult as a result of the adhesive. Chemical decomposition can be generally ineffective since the adhesive is protected by the layers the adhesive bonds together, and the diffusion rate of the chemical can be to slow through the minimal exposure areas available. Furthermore, machining can be difficult or impossible due to the relatively thin adhesive layer, depth of the cut and internal hard features in the adhesive. A sufficiently high temperature such as 360° C. over a period of 24 to 28 hours can be sufficient to decompose silicone based adhesive to allow separation of the components. However, the exposure to the relatively high temperature often renders the layers unusable. Furthermore, a slow heating rate is needed to prevent thermal stress that may damage layers. For example, the different layers of the stack can have different coefficient of thermal expansions which can result in generation of high stresses. In particular, a ceramic layer of the stack can experience a high tensile stress resulting in failure of the ceramic layer.

### SUMMARY

In one form of the present disclosure, a support assembly for use in an electrostatic chuck of semiconductor manufacturing tools is provided. The support assembly includes a first functional element, a second functional element adjacent the first functional element, and an adhesive layer disposed between the first functional element and the second functional element. An intermediate layer is disposed between the first functional element and the adhesive layer. The intermediate layer has a melting temperature less than a temperature that the adhesive layer melts or decomposes at.

In another form of the present disclosure, a method of recycling a support assembly is provided. The method includes providing a support assembly that includes a first functional element, a second functional element, an adhesive layer between the first functional element and the second functional element, and an intermediate layer between the first functional element and the adhesive layer. The method further includes separating the first functional element from the second functional element by melting the intermediate layer without melting or decomposing the adhesive layer.

In still another form of the present disclosure, a support assembly is provided that includes a cooling plate, a substrate adjacent to the cooling plate, and an adhesive layer disposed between the cooling plate and the substrate. An intermediate layer is disposed between the cooling plate and the substrate. The intermediate layer has a melting temperature less than a temperature that the adhesive layer melts or decomposes at.

Further aspects of the present disclosure will be in part apparent and in part pointed out below. It should be understood that various aspects of the disclosure may be implemented individually or in combination with one another. It should also be understood that the detailed description and drawings, while indicating certain exemplary forms of the present disclosure, are intended for purposes of illustration only and should not be construed as limiting the scope of the disclosure.

### DRAWINGS

In order that the disclosure may be well understood, there will now be described various forms thereof, given by way of example, reference being made to the accompanying drawings, in which:

FIG. 1 is a schematic, cross-sectional view of a support assembly for use in an electrostatic chuck of semiconductor manufacturing tools in accordance with one form of the present disclosure;

FIG. 2 is a schematic, cross-sectional view of another support assembly that includes a heater in accordance with principles of the present disclosure;

FIG. 3 is a schematic, cross-sectional view of a further support assembly that includes a heater embedded in a substrate in accordance with principles of the present disclosure;

FIG. 4 is a schematic, cross-sectional view of an even further support assembly that includes an intermediate layer bonded to a substrate in accordance with principles of the present disclosure; and

FIG. 5 is a schematic, cross-sectional view of a support assembly that includes two intermediate layers in accordance with principles of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure or the disclosure's applications or uses. For example, the following forms of the present disclosure are directed to support assemblies for chucks for use in semiconductor processing, and in some instances, electrostatic chucks. However, it should be understood that the support assemblies and systems provided herein may be employed in a variety of applications and are not limited to semiconductor processing applications.

As shown in FIG. 1, a cross-section of a support assembly 10 is illustrated. The support assembly 10 can include a first functional element 12 and a second functional element 14 adjacent the first functional element 12. An adhesive layer 16 can be disposed between the first functional element 12 and the second functional element 14. An intermediate or fusible layer 18 can be disposed between the first functional element 12 and the second functional element 14. For example, the intermediate layer 18 can be disposed between the first functional element 12 and the adhesive layer 16, or as illustrated in FIG. 1, the intermediate layer 18 can be disposed between the second functional element 14 and the adhesive layer 16. The intermediate layer 18 can facilitate separation of the first functional element 12 and the second functional element 14 from one another. In particular, the intermediate layer 18 can have a melting temperature less than a temperature that the adhesive layer 16 melts or decomposes at. Thus, the intermediate layer 18 can be melted to separate the first functional element 12 and the second functional element 14 from one another without damaging the first functional element 12 and/or the second functional element 14.

The adhesive layer 16 can be configured to form a bond with the first functional element 12, the second functional element 14, and/or the intermediate layer 18. For example, the adhesive layer 16 can bond the first functional element 12 and the intermediate layer 18 together, or the adhesive layer 16 can bond the second functional element 14 and the intermediate layer 18 together. However, the support assembly 10 can include more than one adhesive layer 16. For example, an adhesive layer 16 can be used to bond any neighboring layers of the support assembly 10 to one another.

Dimensional control of the assembly 10 can be important. For example, thickness of a layer can affect thermal heat transfer, and variations in a thickness of a layer can result in variation in thermal heat transfer. Thus, the material selected for the adhesive layer 16 can be selected so that the adhesive layer 16 can have a substantially uniform thickness. For example, the adhesive layer 16 can have a thickness of about 0.25 mm to about 1.25 mm. The area of the adhesive layer 16 can be about 300 cm² to about 1,600 cm². The thickness across the area of the adhesive layer 16 can have a deviation of less than about 25 μm. The adhesive layer 16 can include an elastomeric material such as a silicone based polymer. Silicone based polymers can have a desirable combination of temperature performance (i.e., allowable maximum continuous operating temperature and bulk material thermal conductivity, low modulus, elasticity and ease of processing. Thus, a major constituent of the adhesive layer can be silicone. For example, the silicone based polymer can include polydimethylsiloxane (PDMS). Furthermore, the adhesive layer 16 can be a compound. For example, the adhesive layer 16 can also include a filler material such as aluminum oxide (alumina and Al₂O₃), boron nitride, or a boron nitride filler, that has a higher thermal conductivity than the thermal conductivity of the elastomeric material. Thus, the filler material can be used to increase thermal conductivity of the adhesive layer 16. The adhesive layer 16 can be formed by applying a liquid adhesive to a surface of a layer and sandwiching the liquid adhesive between another layer. The liquid adhesive can then be cured to form the adhesive layer 16. Additionally, the liquid adhesive material can be catalyzed to modify its curing temperature.

The intermediate layer 18 is generally a material that has a melting temperature lower than a temperature that the adhesive layer 16 melts or decomposes at. The intermediate layer 18 is located within the assembly such that it is not exposed, in operation, to a temperature that will promote melting or reaching its glass transition temperature. One such location is directly on the upper surface of the cooled base plate, which in one form is the second functional element 14. Thus, the assembly 10 can be heated to a temperature above the melting temperature of the intermediate layer 18 to melt the intermediate layer 18. The first functional element 12 and the second functional element 14 can be separated from one another. The adhesive layer 16 can remain attached to one of the first functional element 12 or the second functional element 14 since the adhesive layer 16 may not have melted or decomposed when the intermediate layer 18 melts.

The melting temperature of the intermediate layer 18 can be less than about 300° C., less than about 250° C., or less than about 200° C. Furthermore, the melting temperature of the intermediate layer 18 can be greater than about 90° C. The melting temperature of the intermediate layer 18 can be greater than a temperature the first functional element 12 and/or second functional element 14 is exposed to during use of the support assembly 10. For example, the melting temperature of the intermediate layer 18 can be at least 30° C. greater than a temperature the intermediate layer 18 is exposed to during operation of the support assembly 10.

The intermediate layer 18 can have a good thermal conductivity such that the intermediate layer 18 does not significantly reduce thermal conductivity of the support assembly 10. For example, the intermediate layer 18 can be a metal or alloy. For instance, the intermediate layer 18 can include or be indium or an indium alloy. Indium has a melting point of about 156° C., and indium may be alloyed with other element(s) to control the melting point. For example, indium may form a eutectic alloy with other elements such as gallium or tin. The indium eutectic alloy can have a melting point less than the melting point of pure indium. Alternatively, other materials such as bismuth can be used as the intermediate layer 18.

The intermediate layer 18 can be formed or applied using a layered process such as deposition. For example, vapor deposition process such as physical vapor deposition (PVD) (e.g., sputtering) or an electrolytic or electroless plating process. The intermediate layer 18 may have a thickness, for example, of about 0.05 μm to about 20 μm. The intermediate layer 18 can be deposited onto the first functional element 12, the second functional element 14, and/or the adhesive layer 16. Furthermore, the intermediate layer 18 can form a bond to a surface that the intermediate layer 18 is deposited on. The intermediate layer 18 can be deposited in series with the formation of the stack of the support assembly 10. For example, the intermediate layer 18 may be deposited on the second functional element 14, and the adhesive layer 16 may be formed on the intermediate layer 18. Alternatively or in addition, the intermediate layer 18 may be deposited onto a functional element 12, 14, and the functional element 12, 14 can be applied to the support assembly 10. For example, the intermediate layer 18 may be deposited onto the first functional element 12, and the first functional element 12 may be applied to the adhesive layer 16 with the intermediate layer 18 facing the adhesive layer 16.

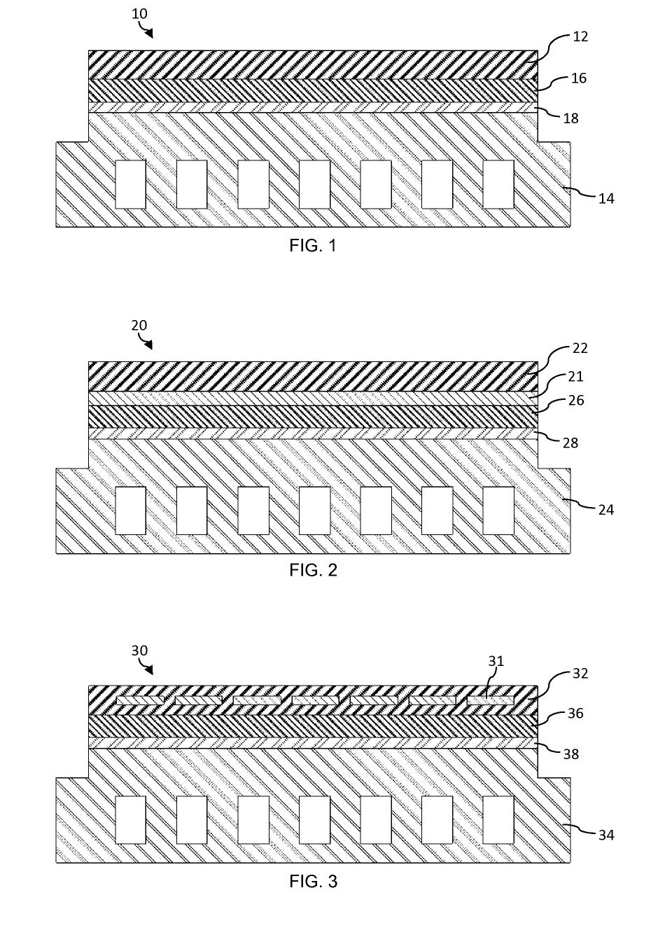

The functional elements 12, 14 can include various components of a support assembly 10 such as a cooling plate, a substrate, a heater, etc. FIG. 1 illustrates one example configuration in which the first functional element 12 is a substrate and the second functional element 14 is a cooling plate. FIGS. 2-5 illustrate additional non-limiting examples.

The substrate can be configured to engage with a wafer such as a wafer used in semiconductor fabrication. Thus, the substrate may be an outermost layer of the support assembly 10. An electrostatic force of the ESC can clamp the wafer to the substrate. The substrate can be a dielectric material such as a ceramic (e.g., alumina). The substrate may be between about 1 mm and about 5 mm. The substrate may have a diameter of about 150 mm to about 450 mm. However, the support assembly 10 may not be an ESC. For example, the substrate may be a sputtering target. It should be understood that these dimensions are merely exemplary and should not be construed as limiting the scope of the present disclosure.

The substrate can be adjacent to a cooling plate. Although various layers and/or elements may be sandwiched between the substrate and the cooling plate, the cooling plate can be in thermal communication with the substrate. Thus, the cooling plate can provide cooling to the substrate and the wafer. The cooling plate can be a good thermal conductor such as a metal or alloy (e.g., aluminum). A coolant can flow through the cooling plate to control the temperature of the cooling plate. For example, during operation, the cooling plate can have a temperature of about −20° C. to about 80° C.

During operation, thermal heat transfer from the substrate to the cooling plate can occur. Thus, the substrate and any layers between the substrate and the cooling plate can affect thermal heat transfer. For example, as previously discussed, a thickness of a layer can affect thermal heat transfer. In particular, a substantially uniform temperature across the entire area of the wafer may be desired. For example, a variation in temperature across the wafer and/or the substrate may be less than about 2° C. Thus, variation in thickness of any of the layers can cause temperature variation across the wafer and the substrate.

A heater may also be disposed between the wafer and the cooling plate. The heater can further control the temperature of the wafer and substrate. For example, the heater can be a resistive heater. The heater may be disposed between the substrate and the cooling plate. Alternatively, the heater may be disposed or embedded within the substrate. The electrical insulating film may have a melting temperature and a decomposition temperature that is greater than the operating temperature of the assembly.

Furthermore, the electrical insulating film may be the intermediate layer 18 or may be configured similar to the intermediate layer 18 such that the melting temperature and the decomposition temperature of the electrically insulating film is less than a temperature that the adhesive layer 16 melts or decomposes at. For example, the electrically insulating films may include a polymer such as polyimide and/or acrylic. The heater circuit can include Inconel heating elements. The heating elements may be used to melt the electrical insulating film. For example, the heating elements may be overdriven to a temperature which will reduce the bond strength of the electrical insulting film to allow separation of the first functional element 12 and the second functional element 14. Since polymers may not have a specific melting temperature point, the melting temperature as used herein can include a temperature in which the polymer has sufficient viscosity for separation the first functional element 12 and the second functional element 14.

As previously discussed, during operation, the support assembly 10 can both hold the wafer and control the temperature of the wafer. For example, during operation, the temperature of the wafer may be between about −20° C. to about 130° C. The support assembly 10 may include additional components or layers. For example, a thermally conductive layer such as aluminum or copper may be disposed between the substrate and the heater to improve uniformity of the heat transfer. For example, any localized heating of the heater may be dispersed with the thermally conductive layer.

A method of recycling a support assembly can include providing a support assembly 10 comprising a first functional element 12, a second functional element 14, an adhesive layer 16 between the first functional element 12 and the second functional element 14, and an intermediate layer 18 between the first functional element 12 and the adhesive layer 14. The functional elements 12, 14, adhesive layer 16 and intermediate layer 18 can have any configuration as described herein. For example, the first functional element 12 can be a cooling plate, and the second functional element 14 can be a cooling plate.

The method can further include separating the first functional element 12 from the second functional element 14 by melting the intermediate layer 18 without melting or decomposing the adhesive layer 16. Thus, the intermediate layer 18 can provide separation of the functional elements 12, 14 of the support assembly 10. Furthermore, the functional elements 12, 14 can be separated from each other without damaging one, some or all of the functional elements 12, 14. A separated functional element 12, 14 can then be used in combination with a different support assembly. For instance, if the first functional element 12 is a substrate, the substrate may wear out during use of the support assembly 10. After the substrate has worn out, the substrate can be separate from the second functional element 14 (e.g., cooling plate or heater) by melting the intermediate layer 18. The ceramic material of the substrate can have a relatively high value, so the substrate may be reclaimed. For example, the substrate can be reworked and reused. The heater may have a relatively low value, so if a heater remains bonded to a component, the heater may be mechanically machined off of the substrate.

The intermediate layer 18 can be melted by various heating methods. For example, an electromagnetic radiation heat source (e.g., lamp) or a hot plate can be used to heat and melt the intermediate layer 18. For instance, a high intensity infrared (IR) heat source (e.g., quartz lamp) can be used. Furthermore, the heating process can be selected to minimize contamination of the support assembly 10. In another example, the intermediate layer 18 may be melted with a heater of the support assembly 10. For instance, the first functional element 12 or the second functional element 14 may be the heater, or the heater may be embedded within a functional element 12, 14. The heater may be overdriven so that heater can heat the intermediate layer 18 to a temperature greater than a temperature the intermediate layer 18 is heated to during use.

Selective heating and cooling of the support assembly 10 can be used to heat the intermediate layer 18 while keeping other components cool and protected. For example, a first side or surface of the support assembly 10 can be heated and a second side or surface of the support assembly 10 can be cooled. In one example, the second functional element 14 can be a cooling plate, and the cooling plate can provide cooling during the melting of the intermediate layer 18. For instance, the cooling can include maintaining a temperature of a functional element 12, 14 below the melting temperature of the intermediate layer 18. As a result, a relatively large temperature differential or gradient can be generated between the first side and the second side. Furthermore, the heating and cooling during melting of the intermediate layer 18 can be used to control thermal expansion of components of the support assembly 10. For example, the first functional element 12 such as a substrate (e.g., ceramic) may have a lower coefficient of thermal expansion (CTE) than a CTE of the second functional element such as a cooling plate (e.g., metal). Thus, the temperature of the first functional element 12 may be raised higher than the temperature of the second functional element 14 to compensate for the difference in CTEs. In particular, ceramic materials can have a relatively low tensile strength as well as a relatively low CTE compared to other materials. Thus, when the ceramic is attached to a material with a higher CTE and both materials are heated, the ceramic can experience a tensile stress that can cause failure of the ceramic.

FIG. 2 is another form of the present disclosure of a support assembly 20 that includes a cooling plate 24 adjacent to a substrate 22. An adhesive layer 26 is between the cooling plate 24 and the substrate 22. An intermediate layer 28 is between the cooling plate 24 and the adhesive layer 28. For example, the intermediate layer 28 may be disposed on the cooling plate. A heater 21 is between the adhesive layer 26 and the substrate 22. The substrate 22 may be bonded to the heater 21 by various methods. For example, a second adhesive layer may bond the substrate 22 and the heater 21 together. The substrate 22 and heater 21 can be separated from the cooling plate 24 by melting the intermediate layer 28. The intermediate layer 28 can be melted with an external heating source or with the heater 21 of the support assembly 20.

FIG. 3 is a further form of the present disclosure of a support assembly 30 that includes a cooling plate 34 adjacent to a substrate 32. An adhesive layer 36 is between the cooling plate 34 and the substrate 32, and an intermediate layer 38 is between the cooling plate 34 and the adhesive layer 38. A heater 31 is embedded within the substrate 32. For example, the heater 31 may include resistive heating wires extending through and parallel with a plane of the substrate 32. The substrate 32 and heater 31 can be separated from the cooling plate 34 by melting the intermediate layer 38 such as with an external heating source or with the heater 31 of the support assembly 30.

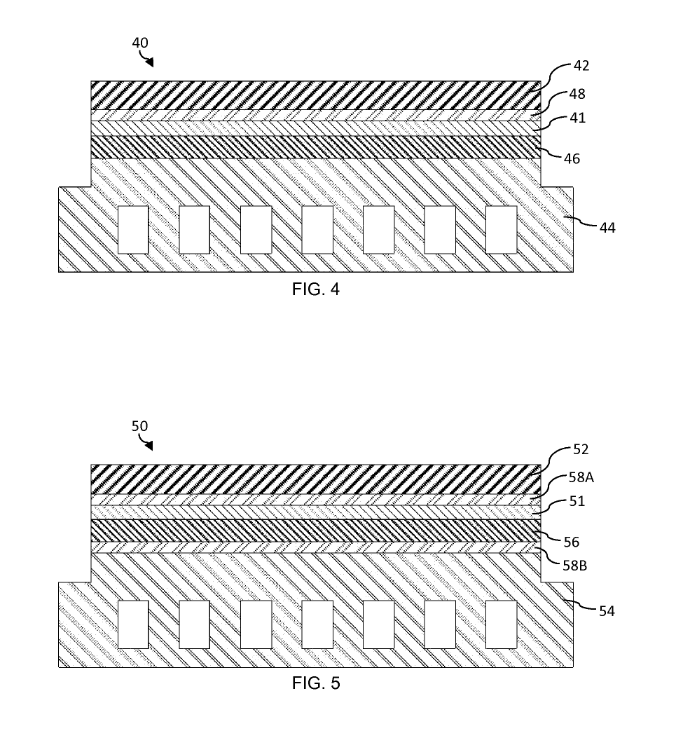

FIG. 4 is an even further form of the present disclosure of a support assembly 40 that includes a cooling plate 44 adjacent to a substrate 42. An adhesive layer 46 is between the cooling plate 44 and the substrate 42. An intermediate layer 48 is disposed between the adhesive layer 46 and the substrate 42. A heater 41 is disposed between the adhesive layer 46 and the intermediate layer 48. The substrate 42 can be separated from the heater 41 by melting the intermediate layer 48 such as with an external heating source or with the heater 41 of the support assembly 40.

FIG. 5 is one more form of the present disclosure of a support assembly 50 that includes a cooling plate 54 adjacent to a substrate 52. An adhesive layer 56 is between the cooling plate 54 and the substrate 52, and a first intermediate layer 58A is between the cooling plate 54 and the adhesive layer 58. A second intermediate layer 58B is between the adhesive layer 56 and the substrate 52. Thus, the substrate 52 can be separated from the heater 51 by melting the first intermediate layer 58A, and the cooling plate 54 can be separated from the heater 51 by melting the second intermediate layer 58B. Similar to the first intermediate layer 58A, the second intermediate layer 58B may have a melting point less than a temperature that the adhesive layer 56 melts or decomposes at.

It should be noted that the disclosure is not limited to the embodiments described and illustrated as examples. A large variety of modifications have been described and more are part of the knowledge of the person skilled in the art. These and further modifications as well as any replacement by technical equivalents may be added to the description and figures, without leaving the scope of the protection of the disclosure and of the present application.

What is claimed is:

1. A support assembly comprising:
a cooling plate;
a substrate adjacent to the cooling plate;
an adhesive layer disposed between the cooling plate and the substrate; and
an intermediate layer disposed between the cooling plate and the substrate, the intermediate layer having a melting temperature less than a temperature that the adhesive layer melts or decomposes at.

2. The support assembly of claim 1, wherein the intermediate layer is disposed on the cooling plate.

3. The support assembly of claim 1, wherein the intermediate layer is applied using a layered process.

4. The support assembly of claim 1, further comprising a heater disposed between the cooling plate and the substrate.

5. The support assembly of claim 4, wherein the intermediate layer is disposed between the heater and the cooling plate.

6. The support assembly of claim 4, wherein the intermediate layer is disposed between the heater and the substrate.

7. The support assembly of claim 4, wherein the intermediate layer is a first intermediate layer, the first intermediate layer disposed between the heater and the cooling plate, and the support assembly further comprises a second intermediate layer disposed between the heater and the substrate, the second intermediate layer having a melting point less than a temperature that the adhesive layer melts or decomposes at.

8. The support assembly of claim 1, further comprising a heater embedded within the substrate.

9. The support assembly of claim 1, wherein a major constituent of the adhesive layer is silicone.

10. The support assembly of claim 9, wherein the silicone comprises polydimethylsiloxane.

11. The support assembly of claim 1, wherein a major constituent of the intermediate layer is Indium.

12. The support assembly of claim 1, wherein the melting temperature of the intermediate layer is less than about 300° C.

13. The support assembly of claim 1, wherein the melting temperature of the intermediate layer is greater than about 40° C.

14. The support assembly of claim 1, wherein the melting temperature of the intermediate layer is at least 30° C. greater than a temperature the intermediate layer is exposed to during operation of the support assembly.

15. The support assembly of claim 1, wherein the melting temperature of the intermediate layer is greater than a temperature the substrate is exposed to during use of the support assembly.

16. The support assembly of claim 1, wherein the intermediate layer has a thickness of about 0.05 μm to about 20 μm.

17. The support assembly of claim 1, wherein the substrate is an electrostatic chuck.

18. The support assembly of claim 1, wherein the substrate is a sputtering target.

19. The support assembly of claim 1, wherein the substrate is a ceramic.

20. A method of recycling a support assembly, the method comprising:
providing a support assembly comprising a first functional element, a second functional element, an adhesive layer between the first functional element and the second functional element, and an intermediate layer between the first functional element and the adhesive layer; and
separating the first functional element from the second functional element by melting the intermediate layer without melting or decomposing the adhesive layer.

21. The method of claim 20, wherein the first functional element is a cooling plate.

22. The method of claim 20, wherein the second functional element is a substrate.

23. The method of claim 20, wherein the melting is conducted by a heater within the support assembly.

24. The method of claim 20, wherein the melting is conducted by an electromagnetic radiation heat source.

25. A support assembly for use in an electrostatic chuck of semiconductor manufacturing tools comprising:
a first functional element;
a second functional element adjacent the first functional element;
an adhesive layer disposed between the first functional element and the second functional element; and
an intermediate layer disposed between the first functional element and the adhesive layer, the intermediate layer having a melting temperature less than a temperature that the adhesive layer melts or decomposes at.

26. The support assembly of claim 25, wherein the intermediate layer is applied using a layered process.

27. The support assembly of claim 25, further comprising a heater embedded within the first functional element.

28. The support assembly of claim 25, wherein a major constituent of the adhesive layer is silicone.

29. The support assembly of claim 28, wherein the silicone comprises polydimethylsiloxane.

30. The support assembly of claim 25, wherein a major constituent of the intermediate layer is Indium.

31. The support assembly of claim 25, wherein the intermediate layer has a thickness of about 0.05 μm to about 20 μm.
